(19) United States
(12) Patent Application Publication
(10) Pub. No.: US 2019/0165097 A1
(43) Pub. Date: May 30, 2019

(54) SEMICONDUCTOR DEVICE HAVING THROUGH HOLE, SOURCE AND GATE ELECTRODE STRUCTURES

(71) Applicant: SANKEN ELECTRIC CO., LTD., Niiza-Shi (JP)

(72) Inventors: Shunsuke FUKUNAGA, Saitama-Shi (JP); Taro KONDO, Niiza-Shi (JP); Shinji KUDOH, Hiki-County (JP)

(73) Assignee: SANKEN ELECTRIC CO., LTD., Niiza-Shi (JP)

(21) Appl. No.: 15/824,256

(22) Filed: Nov. 28, 2017

(51) Int. Cl. H01L 29/06; H01L 29/423; H01L 29/78

(52) U.S. Cl. CPC H01L 29/0657; H01L 29/4236; H01L 23/66; H01L 29/7827; H01L 29/0696

(57) ABSTRACT

A semiconductor device has a through hole penetrating a substrate, an insulating film filling the through hole, a gate electrode and a source electrode. The through hole penetrates a substrate on a first side. A first gate electrode may be embedded in the insulating film. A first source electrode may be embedded in the insulating film deeper than the first gate electrode. A first width of the first opening may be larger than a second width of an internal portion of the through hole. A ratio may be established between the first width and the second width. A second source electrode may be embedded in the insulating film deeper than the first source electrode. A second gate electrode may be embedded deeper than the second source electrode in a vertical direction within the through hole. The first opening and the second opening may be laterally offset.

### BACKGROUND

### 1. Field of the Invention

The present disclosure is generally related to a semiconductor device, and specifically to a semiconductor device having a through hole, source and gate structures.

### 2. Description of Related Art

A trench structure in which a gate electrode is embedded in a trench may be adopted for a semiconductor device, including an integrated power semiconductor device such as a vertical MOSFET or related composite or hybrid device. Examples of trench structures exist in the art having edge termination and breakdown characteristics (for example, see U.S. Pat. No. 5,998,833 (“Patent Literature 1”)). In Patent Literature 1, a source electrode may be positioned in a trench between a gate electrode and the bottom of the trench.

However, devices may still suffer from limitations. For example, the depths of a trench structure in which electrodes are present may often be limited but may vary widely. The variation of the trench depth may lead to undesirable variation in the electric characteristics of the device.

Therefore, there is a need for improvements in electrical characteristics of devices, which may lead to, inter alia, improved edge termination and reduced on-state characteristics.

### SUMMARY

A semiconductor device according to one or more embodiments includes: a through hole that penetrates a substrate on a first side thereof, from a first opening in the substrate; an insulating film filled into the through hole; a first gate electrode embedded in the insulating film; and a first source electrode embedded in the insulating film deeper than the first gate electrode with respect to the first side.

In disclosed embodiments, a first width of the first opening of the through hole on the first side may be larger than a second width of an internal portion of the through hole. A ratio of the first width and the second width may comprise 1.2:1 or greater. One or more embodiments may further comprise: a second source electrode embedded in the insulating film deeper than the first source electrode; and a second gate electrode embedded in the insulating film deeper than the second source electrode, wherein the first and second source electrodes and the first gate electrodes are formed in a vertical direction within the through hole that extends from the first opening to a second opening on a second side of the substrate; and the first and second source electrodes and the first and second gate electrodes are configured to control conduction in both directions with the same electrical characteristics.

One or more additional or alternative embodiments may comprise configurations in which the first opening and the second opening are laterally offset.

Those skilled in the art will recognize additional features and advantages upon reading the following detailed description, and upon viewing the accompanying drawings.

### BRIEF DESCRIPTION OF DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a diagram illustrating a cross-sectional view of a trench configuration of a power semiconductor device having a gate electrode and a source electrode according to a background example;

FIG. 2 is a diagram illustrating a cross-sectional view of a through hole configuration of a power semiconductor device having a gate electrode and a source electrode according to one or more embodiments;

FIG. 3 is a diagram illustrating a cross-sectional view of a through hole configuration of a power semiconductor device having an improved shape, a gate electrode and a source electrode according to one or more alternative or additional embodiments;

FIG. 4 is a diagram illustrating a cross-sectional view of a through hole configuration of a power semiconductor device having an improved modified shape, a gate electrode and a source electrode according to one or more alternative or additional embodiments;

FIG. 5 is a diagram illustrating a cross-sectional view of a through hole configuration of a power semiconductor device having an improved modified through hole shape, and modified positioning of a gate electrode and a source electrode according to one or more alternative or additional embodiments;

FIG. 6A is a diagram illustrating a cross-sectional view of a through hole configuration of a power semiconductor device having multiple structures including an improved modified through hole shape, a gate electrode and a source electrode according to one or more alternative or additional embodiments; and

FIG. 6B is a diagram illustrating a cross-sectional view of a trench configuration of a power semiconductor device having multiple structures including an improved offset through hole shape, a gate electrode and a source electrode according to one or more alternative or additional embodiments.

### DETAILED DESCRIPTION

Embodiments are described with reference to drawings, in which the same constituents are designated by the same reference numerals and duplicate explanation concerning the same constituents may be omitted for brevity and ease of explanation. The drawings are illustrative and exemplary in nature and provided to facilitate understanding of the illustrated embodiments and may not be exhaustive or limiting. Dimensions or proportions in the drawings are not intended to impose restrictions on the disclosed embodiments. For this reason, specific dimensions and the like should be interpreted with the accompanying descriptions taken into consideration. In addition, the drawings include parts whose dimensional relationship and ratios are different from one drawing to another.

Prepositions, such as “on”, “over” and “above” may be defined with respect to a surface, for example a layer surface, regardless of the orientation of the surface in space.

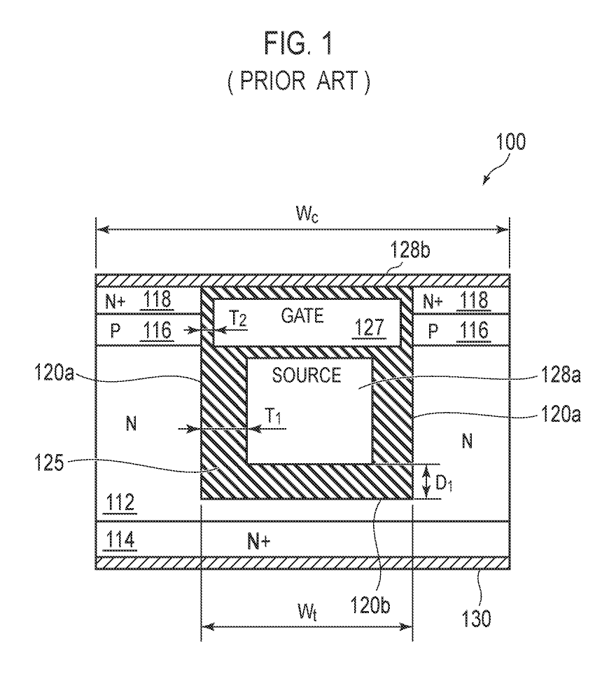

An integrated power semiconductor device structure of the background art, such as that disclosed in Patent Literature 1, the contents of which are incorporated herein by reference is illustrated in FIG. 1. The integrated power semiconductor device may include a unit cell 100 having a predetermined width “W_{c}” (e.g., 1 μm) and may comprise a highly doped drain layer 114 of first conductivity type (e.g., N+), a drift layer 112 of first conductivity type, which may include a linearly graded doping concentration therein, a relatively thin base layer 116 of second conductivity type (e.g., P-type) and a highly doped source layer 118 of the first conductivity type (e.g., N+). A source electrode 128b and drain electrode 130 may also be provided at the first and second faces, in ohmic contact with the source layer 118 and drain layer 114, respectively. The source electrode 128b also preferably forms an ohmic contact with the base layer 116 in a third dimension (not shown). In some examples, the drift layer 112 may be formed by epitaxially growing an N-type in-situ doped monocrystalline silicon layer.

In some examples, the drift layer 112 may have a given thickness, e.g. about 4 μm, on an N-type drain layer 114 (e.g., N+ substrate) having a thickness, e.g. 100 μm, and a first conductivity type doping concentration of greater than about 1×10¹⁸ cm⁻³ (e.g., 1×10¹⁹ cm⁻³). The drift layer 112 may have a linearly graded doping concentration with a maximum concentration of greater than about 5×10¹⁶ cm-3 (e.g., 3×10¹⁷ cm⁻³ at the N+/N non-rectifying junction with the drain layer 114 and a minimum concentration of 1×10¹⁶ cm⁻³ at a depth of 1 μm and continuing at a uniform level to the upper face. The base layer 116 may be formed by implanting P-type dopants, such as boron, into the drift layer 112 at an energy of 100 keV and at a dose level of, for example, 1×10¹⁴ cm². The P-type dopants may be diffused to a depth of 0.5 μm into the drift layer 112. An N-type dopant such as arsenic may then be implanted at an energy of 50 keV and at dose level of 1×10¹⁵ cm⁻².

The N-type and P-type dopants may be diffused simultaneously to a depth of 0.5 μm and 1.0 μm, respectively, to form a composite semiconductor substrate containing the drain, drift, base and source layers. The first conductivity type (e.g., N-type) doping concentration in the drift layer 112 may be less than about 5×10¹⁶ cm⁻³ at the P-N junction with the base layer 116 (i.e., second P-N junction), and may be only about 1×10¹⁶ cm⁻³ at the P-N junction with the base layer 116. The second conductivity type (e.g., P-type) doping concentration in the base layer 116 is also preferably greater than about 5×10¹⁶ cm⁻³ at the P-N junction with the source layer 118 (i.e., first P-N junction). Furthermore, the second conductivity type doping concentration in the base layer 116 at the first P-N junction (e.g., 1×10¹⁷ cm⁻³) is about ten times greater than the first conductivity type doping concentration in the drift region at the second P-N junction (e.g., 1×10¹⁶ cm⁻³).

In disclosed embodiments, a trench having a pair of opposing sidewalls 120a extending in a third dimension (not shown) and a bottom 120b may be formed in the substrate. For the unit cell 100 having a width We of 1 μm, the trench is preferably formed to have a width “Wt” of 0.5 μm at the end of processing. A gate electrode/source electrode insulating region 125, a gate electrode 127 (e.g., polysilicon) and a trench-based source electrode 128a (e.g., polysilicon) are also formed in the trench. Because, in background embodiments, the gate electrode 127 may be made relatively small and does not occupy the entire trench, the amount of gate charge required to drive the unit cell 100 during switching is relatively small. However, inter alia, the size, and positioning of the gate electrode 127 and of the source electrode 128b and the relative positions of the gate electrode 127 and the source electrode 128b within the trench may be set to achieve desired operational characteristics as will be described in greater detail hereinafter.

The trench-based source electrode 128a may be electrically connected to the source electrode 128b in a third dimension (not shown). The portion of the gate electrode/source electrode insulating region 125 extending around at least portions of the source electrode 128a adjacent the trench sidewalls 120a, the trench bottom 120b and the drift layer 112 may also have a thickness “T1” in a range between about 1500 Å and 3000 Å, for example, to inhibit the occurrence of high electric field crowding at the bottom corners of the trench and to provide a substantially uniform potential gradient along the trench sidewalls 120a. However, the portion of the gate electrode/source electrode insulating region 125 extending around side portions of the gate electrode 127 opposite the portions of the trench sidewalls 120a adjacent to the base layer 116 and the source layer 118 preferably has a thickness “T2” of less than about 750 Å, and more preferably about 500 Å to maintain the threshold voltage of the device at about 2-3 volts. As will be described hereinafter, the thicknesses T1 and T2 may be changed along with position of the electrodes, penetration depth and shape of the trench wall.

In the illustrated embodiments, the specific on-resistance of the unit cell 100 may be relatively high. Moreover, the specific the high frequency figure-of-merit (HFOM), defined as (R_{on, Sp} (Q_{GS}+Q_{GD}))⁻¹, where Q_{GS} and Q_{GD} represent the gate-source and gate-drain charge per unit area may be acceptable.

However, in accordance with one or more embodiments as will be described hereinafter, the operational characteristics of an integrated power semiconductor device may be improved. Specifically, a trench structure may be provided that reliably penetrates into the substrate at a given depth and according to a given width and other shape related parameters and a gate electrode and source electrode may be embedded in the insulated film.

### First Embodiment

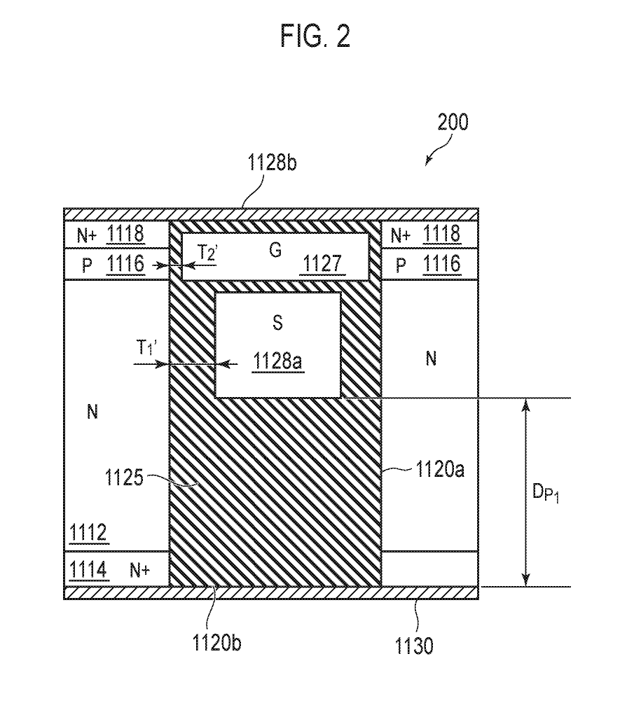

FIG. 2 illustrates a cross-sectional view of a power semiconductor device having a unit cell 200 in accordance with at least a first embodiment. Except as described in connection with disclosed and illustrated embodiments, the description of FIG. 2 may be applicable to the subsequent figures and embodiments where the description would be redundant. The unit cell 200 may comprise a highly doped drain layer 1114 of first conductivity type (e.g., N+), a drift layer 1112 of first conductivity type, which may include a linearly graded doping concentration therein, a relatively thin base layer 1116 of second conductivity type (e.g., P-type) and a highly doped source layer 1118 of the first conductivity type (e.g., N+). A source electrode 1128b and drain electrode 1130 may also be provided at the first and second faces, in ohmic contact with the source layer 1118 and drain layer 1114, respectively. The source electrode 1128b also preferably forms an ohmic contact with the base layer 1116 in a third dimension (not shown). In some examples, the drift layer 1112 may be formed by epitaxially growing an N-type in-situ doped monocrystalline silicon layer.

In some examples, the drift layer 1112 may have a given thickness, e.g. about 4 μm, on an N-type drain layer 1114 (e.g., N+ substrate) having a thickness, e.g. 100 μm, and a first conductivity type doping concentration of greater than about 1×10¹⁸ cm⁻³ (e.g., 1×10¹⁹ cm⁻³). The drift layer 1112 may have a linearly graded doping concentration with a maximum concentration of greater than about 5×10¹⁶ cm⁻³ (e.g., 3×10¹⁷ cm⁻³ at the N+/N non-rectifying junction with the drain layer 1114 and a minimum concentration of 1×10¹⁶ cm⁻³ at a depth of 1 μm and continuing at a uniform level to the upper face. The base layer 1116 may be formed by implanting P-type dopants, such as boron, into the drift layer 1112 at an energy of 100 keV and at a dose level of, for example, 1×10¹⁴ cm². The P-type dopants may be diffused to a depth of 0.5 μm into the drift layer 1112. An N-type dopant such as arsenic may then be implanted at an energy of 50 keV and at dose level of 1×10¹⁵ cm⁻².

The N-type and P-type dopants may be diffused simultaneously to a depth of 0.5 μm and 1.0 μm, respectively, to form a composite semiconductor substrate containing the drain, drift, base and source layers. The first conductivity type (e.g., N-type) doping concentration in the drift layer 1112 may be less than about 5×10¹⁶ cm⁻³ at the P-N junction with the base layer 1116 (i.e., second P-N junction), and may be only about 1×10¹⁶ cm⁻³ at the P-N junction with the base layer 1116. The second conductivity type (e.g., P-type) doping concentration in the base layer 1116 is also preferably greater than about 5×10¹⁶ cm⁻³ at the P-N junction with the source layer 1118 (i.e., first P-N junction). Furthermore, the second conductivity type doping concentration in the base layer 1116 at the first P-N junction (e.g., 1×10¹⁷ cm⁻³) is about ten times greater than the first conductivity type doping concentration in the drift region at the second P-N junction (e.g., 1×10¹⁶ cm⁻³).

Unlike unit cell 100, in accordance with one or more embodiments, a through hole having a pair of opposing sidewalls 1120a extending in a third dimension (not shown) may be formed in the substrate. The through hole may be formed penetrating the substrate completely.

The through hole-based source electrode 1128a may be electrically connected to the source electrode 1128b in a third dimension (not shown). The portion of the gate electrode/source electrode insulating region 1125 extending around at least portions of the source electrode 1128a adjacent the trench sidewalls 1120a has a thickness T1′.

However, the portion of the gate electrode/source electrode insulating region 1125 extending around side portions of the gate electrode 1127 opposite the portions of the sidewalls 1120a adjacent to the base layer 1116 and the source layer 1118 preferably has a thickness T2′. The through hole may have a penetration depth beneath a lower surface of the source electrode 1128a of D_{P1}. In other words, the through hole may entirely penetrate the substrate. By making the through hole structure as disclosed herein, variation in electrical characteristics can be reduced.

### Second Embodiment

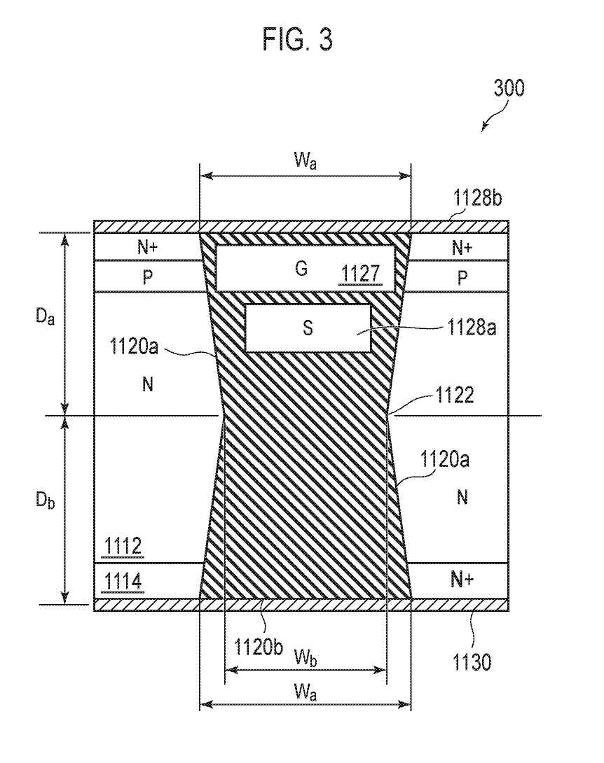

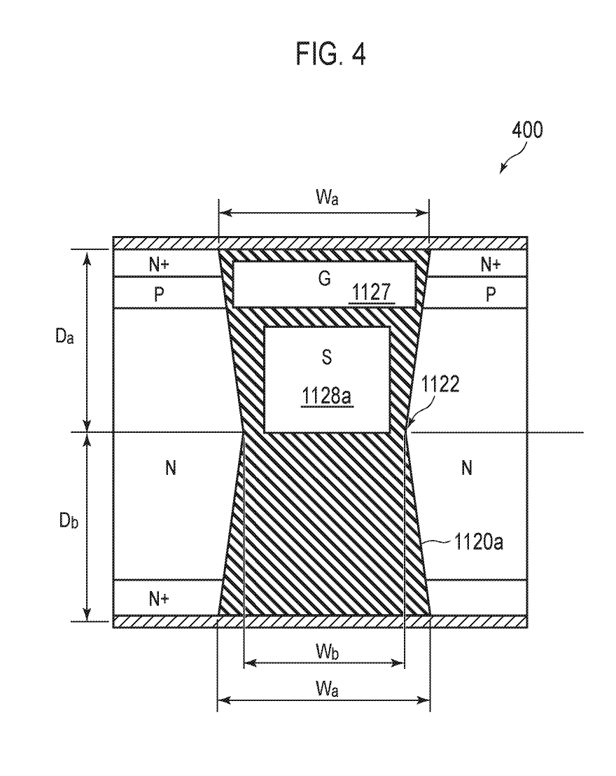

FIG. 3 and FIG. 4 illustrate cross-sectional views of a through hole configuration of a power semiconductor device. FIG. 3 and FIG. 4 will be described with reference to the unit cell 200 of FIG. 2 such that duplicate descriptions of elements previously described in connection with FIG. 2 will be omitted for simplicity. In the example illustrated in FIG. 3, a unit cell 300 is described in accordance with at least a second embodiment having an improved through hole shape, a gate electrode and a source electrode. In one or more alternative or additional embodiments, the sidewalls 1120a may be configured in a tapering shape, throughout at least a portion or portions along the depth of the through hole. For example, the through hole may extend from the source layer 1118 to a first depth Dₐ in the drift layer 1112. From the portion of the through hole sidewalls 1120a at the source layer 1118 to the depth Dₐ, the distance between the through hole sidewalls 1120a decreases from a width Wₐ to W_{b}. From a point 1122 on the through hole sidewalls 1120a, where the distance between sidewalls 1120a is at the width W_{b}, to the through hole bottom 1120b, which may be expressed as D_{b}, the distance between the sidewalls 1120a may increase back to a width Wₐ. The penetration depth of the through hole, from the bottom of the source electrode 1128a to the through hole bottom 1120b, may be Dₚ₂. In the present example, the widths at Wₐ may be equivalent. A ratio of the width Wₐ and the width W_{b} may be 1.2:1 or greater. Further, the depths Dₐ and D_{b} may be equivalent. With reference to FIG. 4, in modified embodiments, the placement of the source electrode 1128a in a unit cell 400 may be set such that the bottom surface of the source electrode 1128a may be at or beyond the point 1122 toward the drain layer 1114. In such an example, the penetration depth of the through hole, from the bottom of the source electrode 1128a to the through hole bottom 1120b, may be Dₚ₃.

### Third Embodiment

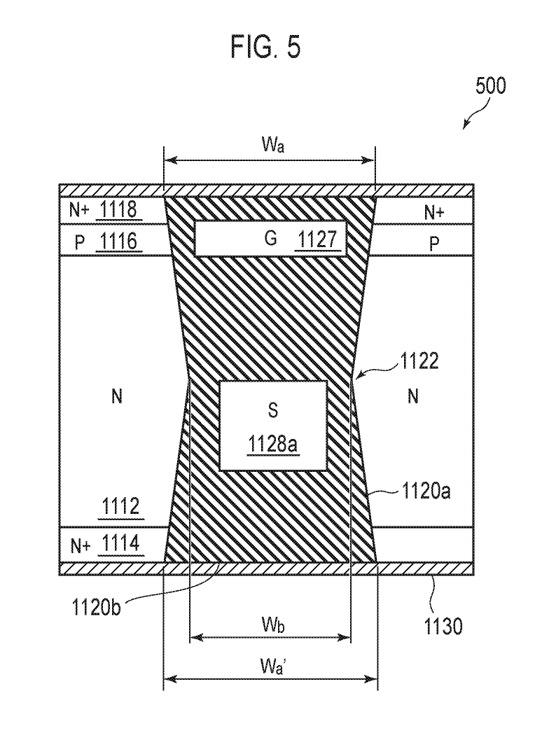

FIG. 5 illustrates a cross-sectional view of a through hole configuration of a power semiconductor device having a unit cell 500 in accordance with at least a third embodiment having an improved shape, a gate electrode and a source electrode. FIG. 5 will be described with reference to the unit cells 200, 300 and 400 of FIG. 2, FIG. 3 and FIG. 4 such that duplicate descriptions of elements previously described in the foregoing figures will be omitted for simplicity. The described one or more embodiments include a through hole having sidewalls with different widths along the depth of the through hole. For example, in some embodiments, the width at the source layer 1118 may be different from the width at the drift layer 1112 or the drain layer 1114. For example, the width at the point 1122 may be W_{b}, the width at the source layer 1118 may be Wₐ and the width at the drift layer 1112 or the drain layer 1114 may be Wₐ′.

The relationships between the different widths of the through hole may be set according to the relationship in EQ(1):

Wa≥Wa′>Wb EQ(1)

Further in accordance with one or more embodiments illustrated in FIG. 5, the gate electrode 1127 may be positioned within the through hole such that the bottom of the gate electrode 1127 is above the point 1122, e.g. where the width is at a minimum (W_{b}). The source electrode 1128a may be positioned within the through hole such that the top of the source electrode 1128a is below the point 1122.

### Fourth Embodiment

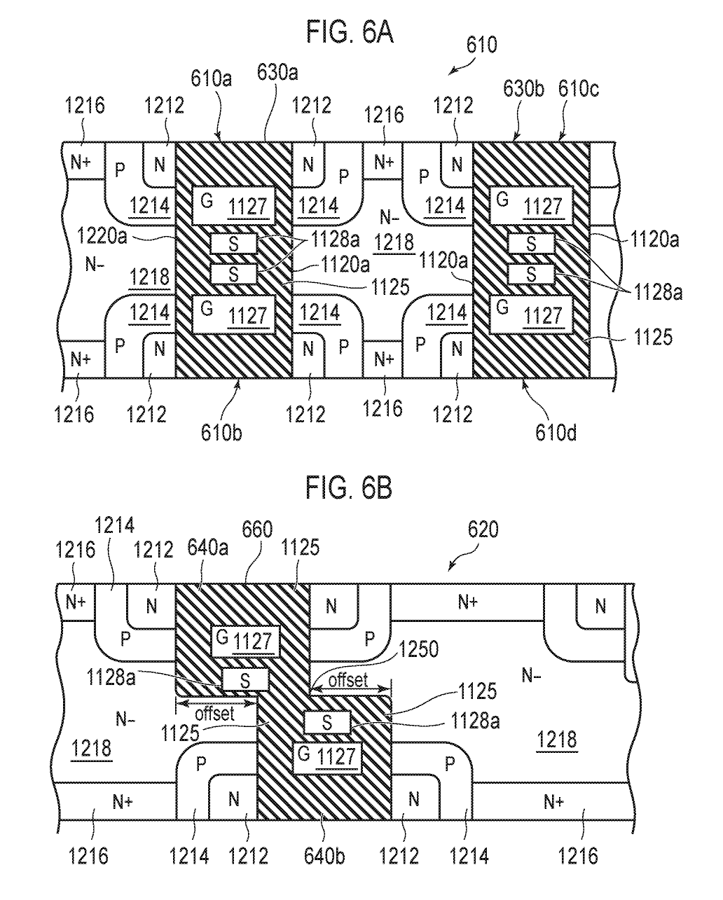

FIG. 6A and FIG. 6B will be described with reference to the unit cells 200, 300, 400 and 500 of FIG. 2, FIG. 3, FIG. 4 and FIG. 5 such that duplicate descriptions of elements previously described in the foregoing figures will be omitted for simplicity.

FIG. 6A illustrates a cross-sectional view of a series of unit cells 610 having exemplary through hole configurations of a series of integrated power semiconductor devices in accordance with at least a fourth embodiment having improved shapes, and ganged configurations of gate and source electrodes. As shown in FIG. 6A, a series of unit cells 610a, 610b, 610c, and 610d may be arranged in a first through hole 630a and a second through hole 630b. For example, unit cells 610a and 610b may be arranged in the first through hole 630a and unit cells 610c and 610d may be arranged in the second through hole 630b.

In the first through hole 630a, the unit cell 610a may be arranged from a first opening in the substrate on a first side with a first gate electrode 1127 embedded in the electrode insulating region 1125 nearest the first opening and a first source electrode 1128a embedded in the electrode insulating region 1125 deeper into the first through hole 630a. A second source electrode 1128a may be embedded in the electrode insulating region 1125 deeper into the first through hole 630a than the first source electrode 1128a. A second gate electrode 1127 may be embedded in the electrode insulating region 1125 deeper into the first through hole 630a than the second source electrode 1128a such that it is near a second opening in the substrate on a second side. The first through hole 630a may have through hole sidewalls 1120a. The substrate may comprise layers of material of various conductivity types as illustrated and described, for example, in connection with unit cells 200, 300, 400, and 500. For example, on a first side, the through holes of the unit cells 610 may penetrate a substrate that comprise a doped first layer 1212 of a first conductivity type (e.g., N), a first layer 1214 of a second conductivity type (e.g., P-type) and a lightly doped layer 1218 (e.g., N−). On the first side, a highly doped layer 1216 of the first conductivity type (e.g., N+) separates the through holes and surrounding layers (e.g., layers 1212, 1214, of adjacent cells. On a second side, the through holes 630a and 630b of the unit cells 610a and 610b may penetrate the substrate e.g., from a second opening of the through holes 630a and 630b in a mirror image configuration that comprise a second doped layer 1212 of the first conductivity type (e.g., N), a second layer 1214 of a second conductivity type (e.g., P-type) and a second highly doped layer 1216 of the first conductivity type (e.g., N+) that separates the through holes and surrounding layers (e.g., layers 1212, 1214, of adjacent cells. The device, including the gate and source electrodes may be configured to be controlled from either side to produce the same operational characteristics. In some embodiments, the device, including the gate and source electrodes may be configured to be controlled from either side to produce different operational characteristics depending on the relative construction of the elements per side.

### Fifth Embodiment

FIG. 6B illustrates a cross-sectional view of a series of unit cells 620 having exemplary through hole configurations of a series of integrated power semiconductor devices in accordance with at least a fifth embodiment having improved shapes, offsets, and ganged configurations of gate and source electrodes. As shown in FIG. 6B, a series of unit cells 640a and 640b may be arranged in a first through hole 660. A fifth embodiment may differ from a fourth embodiment in that a lateral offset 1250 may be provided between the unit cells 640a and 640b along the length of the through hole 660.

In accordance with the above described embodiments, electrical characteristics such as ON resistance may be improved (e.g., lowered in the case on ON resistance).

Although one or more embodiments as described above herein may be directed to devices having a particular arrangement of layers with conductivity types, e.g. N, N+, P, and so on, other embodiments may be directed to devices in which the conductivity types are reversed or otherwise modified. Furthermore, the above-described aspects may be combined with each other as practicable within the contemplated scope of embodiments. The above described embodiments are to be considered in all respects as illustrative, and not restrictive. The illustrated and described embodiments may be extended to encompass other embodiments in addition to those specifically described above without departing from the intended scope of the invention. The scope of the invention is to be determined by the appended claims when read in light of the specification including equivalents, rather than solely by the foregoing description. Thus, all configurations including configurations that fall within equivalent arrangements of the claims are intended to be embraced in the invention.

1. A semiconductor device comprising:
a through hole that penetrates a substrate on a first side thereof, from a first opening in the substrate;
an insulating film filled into the through hole
a first gate electrode embedded in the insulating film; and
a first source electrode embedded in the insulating film deeper than the first gate electrode with respect to the first side.

2. The semiconductor device according to claim 1, wherein a first width of the first opening of the through hole on the first side is larger than a second width of an internal portion of the through hole.

3. The semiconductor device according to claim 2, wherein a ratio of the first width and the second width comprises 1.2:1 or greater.

4. The semiconductor device according to claim 1, further comprising:
a second source electrode embedded in the insulating film deeper than the first source electrode; and
a second gate electrode embedded in the insulating film deeper than the second source electrode, wherein:
the first and second source electrodes and the first and second gate electrodes are formed in a vertical direction within the through hole that extends from the first opening to a second opening on a second side of the substrate; and
the first and second source electrodes and the first and second gate electrodes are configured to be controlled for conduction in both directions through the through hole with the same electrical characteristics.

5. The semiconductor device of claim 4, wherein the first opening and the second opening are laterally offset.
